(19) United States
(12) Patent Application Publication
(10) Pub. No.: US 2011/0307418 A1
(43) Pub. Date: Dec. 15, 2011

(54) MULTI-METERING OF ELECTRIC POWER CONSUMPTION

(76) Inventor: Baruch Bouzaglo, Paris (FR)

(21) Appl. No.: 13/202,886

(22) PCT Filed: Feb. 23, 2010
(86) PCT No.: PCT/IB2010/050789

§ 371 Date: Aug. 23, 2011

Related U.S. Application Data
(60) Provisional application No. 61/154,643, filed on Feb. 23, 2009.

(51) Int. Cl. G01R 21/00; G06F 19/00

(52) U.S. Cl. 705/412; 702/62

(57) ABSTRACT

An electric metering system comprising a plurality of metering devices controlled by a metering controller. Each of the metering devices provides the controller with instantaneous measurements of electric current within an associated electric conductor. The metering controller is operative to collect the measurement information, compute consumption information, store the information and retrieve the information for each metering device independently.

### FIELD AND BACKGROUND OF THE INVENTION

The present invention relates to measuring the consumption of electric power and, more particularly, but not exclusively to electric current metering devices.

Devices that measure the consumption of electric power are used in almost any apartment, house, office, shop, industrial facility, etc. This metering device records the consumption of electrical power, or energy, mainly for the purpose of billing the consumer. Similar devices are also available and used for measuring the consumption of water, gas, etc. Such metering devices are predominantly analog (electromechanical), but digital models are also in use. Since the purpose of the metering device is to provide data for billing, a single metering device is installed for each bill paying entity (subscriber). While this is effective from the point of view of the utility operator, the subscriber lacks detailed report of the local and temporal distribution of consumption and the associated costs.

Remote metering is also available, enabling the utility operator to collect meter reading without the need to access the meter itself. Remote metering can provide reading just outside the premises, relieving both the operator and the proprietor from the need to schedule access to the premises. Remote metering can also provide wireless reading from the street, or from a moving car. Other technologies of remote metering enable the operator to collect metering data from a central location, via long distance communication networks. Many types of communication technologies are offered for remote metering, including point-to-point cables, power-line carrier (PLC), telephony, and radio (including cellular). For example, the MT423—Industrial poly-phase meter, available from Iskraemeco, d.d., Savska loka 4, 4000 Kranj, Slovenia. Has a built-in GSM cellular modem.

However, the penetration of intelligent remote metering to the market is still very low, and the main reason is the high cost of the remote metering devices, compared with the conventional electromechanical devices.

It is obvious that an intelligent remote meter device can provide the subscriber, as well as the utility operator, with detailed information about the consumption patterns and habits, that would eventually lead to smaller bills, higher efficiency, and less pollution. However, implementing such sophistication would further increase the cost of the metering device.

There is thus a widely recognized need for, and it would be highly advantageous to have, an intelligent remote metering system devoid of the above limitations.

### SUMMARY OF THE INVENTION

According to one aspect of the present invention there is provided an electric metering system containing: a metering controller, and a plurality of metering devices. Each of the metering devices is operative to provide instantaneous measurement of electric current within an associated electric conductor. Each of the plurality of metering devices is operative to communicate with the metering controller. Wherein the metering devices provide the instantaneous measurements to the metering controller; and wherein the metering controller is operative to collect, store and retrieve the instantaneous measurements for each of the metering devices independently.

According to another aspect of the present invention there is provided an electric metering system wherein the metering controller is additionally operative to provide measurement of energy consumed via each of the electric conductors within a predefined period.

According to still another aspect of the present invention there is provided an electric metering system wherein the metering controller is additionally operative to store and retrieve the measurements of energy.

According to yet another aspect of the present invention there is provided an electric metering system wherein the metering controller and the plurality of metering devices are connected over a network, wherein the network is a cable network and/or a wireless network.

Also, according to another aspect of the present invention there is provided an electric metering system wherein the wireless network being at least one of WiFi, Bluetooth and Zigbee.

Further according to another aspect of the present invention there is provided an electric metering system wherein the cable network is using a power-line carrier (PLC) communication technology.

Still further according to another aspect of the present invention there is provided an electric metering system wherein the metering controller is additionally operative to communicate with at least one of a computer, a PDA and a central server.

Yet further according to another aspect of the present invention there is provided an electric metering system wherein the metering controller is operative to communicate the central server over a network, and wherein the network is at least one of a cable network and a wireless network.

Even further according to another aspect of the present invention there is provided an electric metering system wherein the wireless network is at least one of a public land mobile network (PLMN) and wireless metropolitan network (MAN).

Additionally, according to another aspect of the present invention there is provided a method for measuring distributed consumption, the method including
measuring instantaneous consumption, substantially concurrently, at a plurality of measuring points to provide instantaneous consumption measurement for each measuring point;
communication the instantaneous consumption measurements to a local controller;
computing, at the local metering controller, periodical consumption measurement, for each the measuring points;
storing the periodical consumption measurement at the local metering controller for later retrieval; and
providing the periodical consumption measurement independently of each other.

Additionally, according to yet another aspect of the present invention there is provided a method for measuring distributed consumption wherein at least one of the steps of:
measuring instantaneous consumption;
communication the instantaneous consumption measurements; and
computing periodical consumption measurements;

contains performing the at least one step in a manner that is at least one of continuous and repeating.

Additionally, according to still another aspect of the present invention there is provided a method for measuring distributed consumption additionally containing the step of communicating periodical consumption measurements to a user, and/or a local computerized device, and/or a remote server.

Also, according to another aspect of the present invention there is provided a method for measuring distributed consumption wherein the consumption measurements include consumption of electric energy, electric power, and/or electric current.

Further, according to still another aspect of the present invention there is provided a method for measuring distributed consumption wherein the periodical consumption measurements are performed for predefined periods.

Still further, according to still another aspect of the present invention there is provided a method for measuring distributed consumption wherein the predefined period is independently set for each measuring point.

Unless otherwise defined, all technical and scientific terms used herein have the same meaning as commonly understood by one of ordinary skill in the art to which this invention belongs. The materials, methods, and examples provided herein are illustrative only and not intended to be limiting. Except to the extend necessary or inherent in the processes themselves, no particular order to steps or stages of methods and processes described in this disclosure, including the figures, is intended or implied. In many cases the order of process steps may varied without changing the purpose or effect of the methods described.

Implementation of the method and system of the present invention involves performing or completing certain selected tasks or steps manually, automatically, or any combination thereof. Moreover, according to actual instrumentation and equipment of preferred embodiments of the method and system of the present invention, several selected steps could be implemented by hardware or by software on any operating system of any firmware or any combination thereof. For example, as hardware, selected steps of the invention could be implemented as a chip or a circuit. As software, selected steps of the invention could be implemented as a plurality of software instructions being executed by a computer using any suitable operating system. In any case, selected steps of the method and system of the invention could be described as being performed by a data processor, such as a computing platform for executing a plurality of instructions.

### BRIEF DESCRIPTION OF THE DRAWINGS

The invention is herein described, by way of example only, with reference to the accompanying drawings. With specific reference now to the drawings in detail, it is stressed that the particulars shown are by way of example and for purposes of illustrative discussion of the preferred embodiments of the present invention only, and are presented in order to provide what is believed to be the most useful and readily understood description of the principles and conceptual aspects of the invention. In this regard, no attempt is made to show structural details of the invention in more detail than is necessary for a fundamental understanding of the invention, the description taken with the drawings making apparent to those skilled in the art how the several forms of the invention may be embodied in practice.

In the drawings:

FIG. 1 is a simplified is a simplified illustration of an electric-power multi-metering device according to a preferred embodiment of the present invention.

FIGS. 2A, 2B, and 2C are three simplified illustrations of three embodiments of a single-phase electric-power measuring-device, which is a part of the electric-power multi-metering device;

FIG. 3 is a simplified block diagram of the multi-metering controller, which is another part of the electric-power multi-metering device;

FIG. 4 is a simplified illustration of a network of multi-metering devices;

FIG. 5 is a simplified illustration of an integrated multi-metering device;

FIG. 6 is a simplified illustration of a remotely controlled multi-metering device according to a preferred embodiment of the present invention;

FIG. 7 is a simplified illustration of a subscriber-identifiable multi-metering controller according to a preferred embodiment of the present invention; and

FIG. 8 is a simplified illustration of a utility billing system according to a preferred embodiment of the present invention.

### DETAILED DESCRIPTION OF THE INVENTION

The principles and operation of an electric-power multi-metering device according to the present invention may be better understood with reference to the drawings and accompanying description.

Before explaining at least one embodiment of the invention in detail, it is to be understood that the invention is not limited in its application to the details of construction and the arrangement of the components set forth in the following description or illustrated in the drawings. The invention is capable of other embodiments or of being practiced or carried out in various ways. Also, it is to be understood that the phraseology and terminology employed herein is for the purpose of description and should not be regarded as limiting.

It is also appreciated that the concept of the multi-metering device described herein by example of an electric-power multi-metering device, also applies for other types of metering devices, such as for measuring the consumption of gas, water, etc.

In this document, an element of a drawing that is not described within the scope of the drawing and is labeled with a numeral that has been described in a previous drawing has the same use and description as in the previous drawings. Similarly, an element that is identified in the text by a numeral that does not appear in the drawing described by the text, has the same use and description as in the previous drawings where it was described.

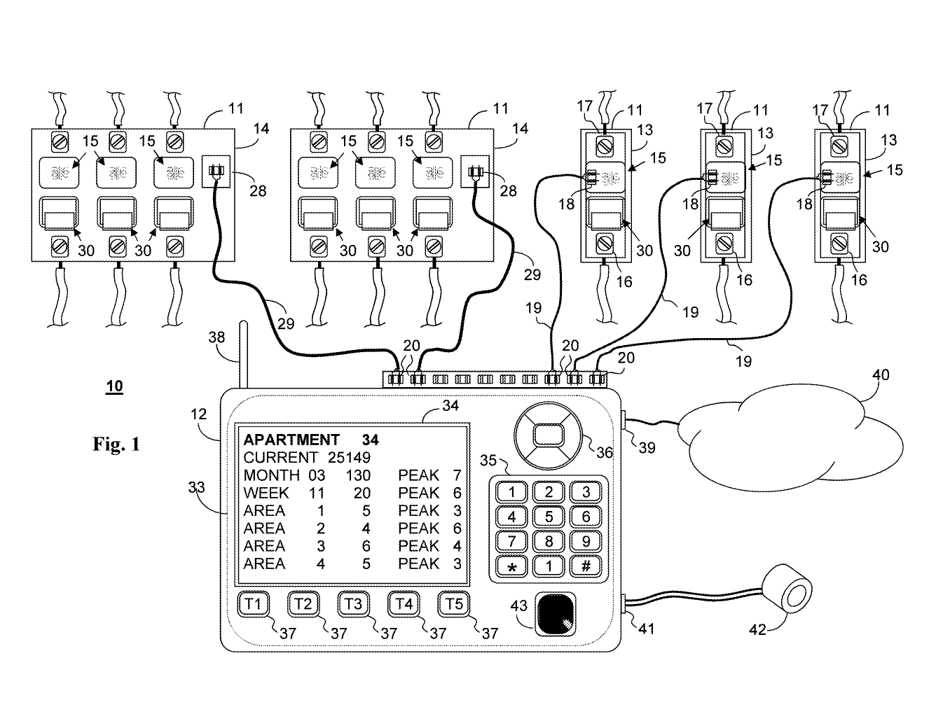

Reference is now made to FIG. 1, which is a simplified illustration of an electric-power multi-metering device 10, according to a preferred embodiment of the present invention

As shown in FIG. 1, the multi-metering device 10 contains two main components:

at least one, but preferably a plurality, of electric-power measuring-devices 11; and

a multi-metering controller 12, connected to the electric-power measuring-devices 11.

In FIG. 1, the electric-power measuring-devices 11 referenced by numeral 13 are preferably single-phase electric-power measuring-devices, while the electric-power measuring-devices 11 referenced by numeral 14 are preferably three-phase electric-power measuring-devices.

Preferably, the single-phase electric-power measuring-device 13 contains a transformer element 15. The primary coil of the transformer connects between the input-power connector 16 and the output-power connector 17, while the secondary coil of the transformer connects, via connector 18, and an electric cable 19, to an input port 20 of the multi-metering controller 12.

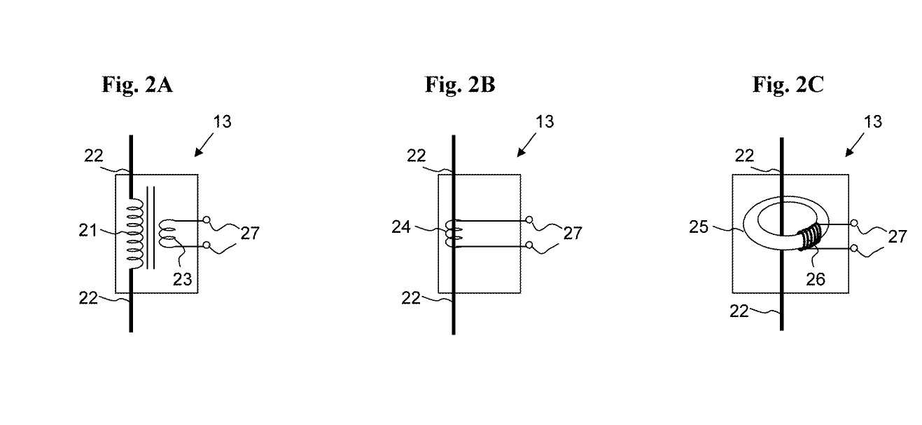

Reference is now made to FIGS. 2A, 2B, and 2C, which are three simplified illustrations of three embodiments of the single-phase electric-power measuring-device 13 according to a preferred embodiment of the present invention.

In FIG. 2A the single-phase electric-power measuring-device 13 is a transformer as described above, including a primary coil 21 connecting to the electric conductor 22 carrying the electric power, and a secondary coil 23.

In FIG. 2B the single-phase electric-power measuring-device 13 is a coil 24 into which the electric conductor carrying the electric power is inserted.

In FIG. 2C the single-phase electric-power measuring-device 13 is a toroid 25, over which a coil 26, is wrapped, and through which electric conductor carrying the electric power is inserted.

Terminals 27 carry the measurement signal to the multi-metering controller 12.

It is appreciated that the embodiments of FIGS. 2A, 2B, and 2C apply also to the three-phase electric-power measuring-device 14.

Turning back to FIG. 1, the three-phase electric-power measuring-device 14 preferably contains three transformers 15, of which the secondary coils are interconnected and, via connector 28, connected via a cable 29, to an input port 20 of the multi-metering controller 12.

As shown in FIG. 1, the single-phase electric-power measuring-device 13, are additionally equipped with fuses 30. Similarly, the three-phase electric-power measuring-devices 14 are also equipped with fuses 31, preferably a fuse 30 for each phase. It is appreciated that the fuses 32 are optional and the electric-power measuring-devices 11 may not contain the fuses 30.

As shown in FIG. 1, the multi-metering controller 12 contains 10 input ports 20, connecting to up to 10 units of single-phase electric-power measuring-device 13, and/or three-phase electric-power measuring-device 14. It is appreciated that the number of ports 20 is arbitrary and the number of 10 ports is provided as an example.

Optionally but preferably, the multi-metering controller 12 contains a user interface 33, preferably including:
a user output interface, preferably including a display 34; and
a user input interface, which preferably includes a keyboard 35, a pointing device 36, and programmable special function keys 37;

one or more communication interfaces, such as:
a radio network interface including an antenna 38;
a cable network interface including a connector 39 connected by cable to network 40;
a PLC connector 41 to a power-line carrier interface 42.

Optionally, the multi-metering controller 12 contains a biometric identification device 43. It is appreciated that biometric user identification can use a finger-print scanning device (such as available from Ultra-Scan Corporation, 4240 Ridge Lea Rd, Amherst, N.Y. 14226, USA), an electro-physiological sensing device (such as available from Idesia Ltd. 7 Halamish Street, Caesarea Industrial Park, 38900 Israel), etc. Preferably, the biometric device identifies the user in real-time.

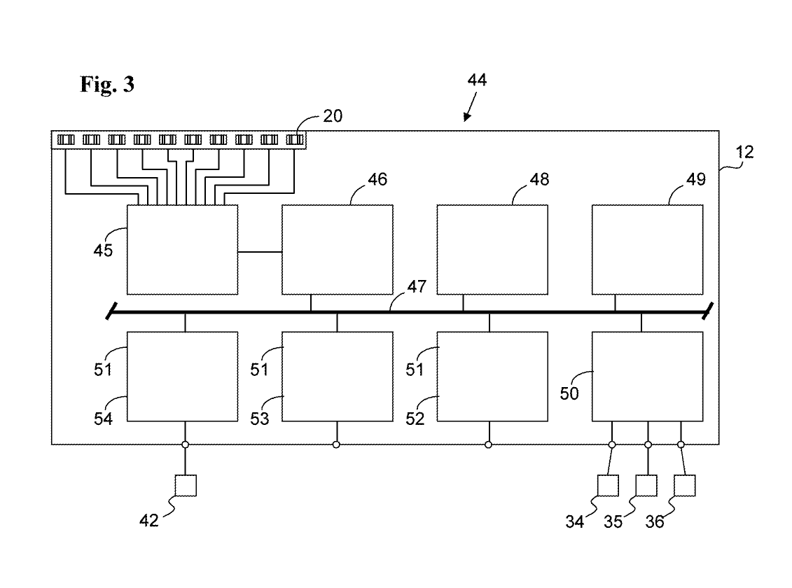

Reference is now made to FIG. 3, which is a simplified block diagram 44 of the multi-metering controller 12 according to a preferred embodiment of the present invention.

The multi-metering controller 12 preferably contains the input ports 20, preferably connected to a selector module 45. The selector module 45 preferably connects to an analog to digital converter 46. The digital converter 46 preferably connects to a bus 47. The bus 47 preferably connects to a processor 48, a memory or storage module 49, a user interface module 50, and one or more communication modules 51.

It is appreciated that the memory or storage module 49 preferably includes a read-only memory for storing software program, a random access memory for storing temporary data, and non-volatile memory for storing data for long periods.

It is appreciated that the user-interface module 50 preferably includes controllers for the display 34, the keyboard 35, the pointing device 36, and the programmable function keys 37.

Preferably, one communication module 51 is a local communication module 52, enabling the multi-metering controller 12 to communicate locally, preferably using a local area network (LAN), or a personal area network (PAN), whether cable-based or wireless, such as Ethernet, Universal Serial Bus (USB), WiFi (IEEE 802.11x), Bluetooth (iEEE802.15.1), Zigbee (IEEE802.15.4), RS-485, etc. The local communication module 52 enables the multi-metering controller 12 to communicate with other multi-metering controllers 12, and/or with local computers, such as home PCs, and/or with portable devices such as laptop computers, PDAs and handheld terminals.

Preferably, another communication module 51 is a wide area communication module 53, enabling the multi-metering controller 12 to communicate with remote servers, preferably using a wide area network or a metropolitan area network, whether cable-based or wireless, such as an Internet protocol (IP) network, The Internet, a trunked radio network (e.g. TETRA), a PLMN network (e.g. a cellular network), WiMAX (IEEE802.16), etc.

Preferably, another communication module 51 is a PLC communication module 54, enabling the multi-metering controller 12 to communicate either with other, local multi-metering controllers 12, and/or with a remote server.

The multi-metering device 10 contains one multi-metering controller 12 and preferably a plurality of electric-power measuring-devices 11. Preferably, the multi-metering device 10 measures, stores, analyzes and communicates to external computing devices the power consumption for each electric-power measuring-device 11 independently. Hence, the multi-metering device 10 functions as a plurality of independent metering devices. However, the cost of the relatively expensive multi-metering controller 12 is divided between the plurality of the electric-power measuring-devices 11.

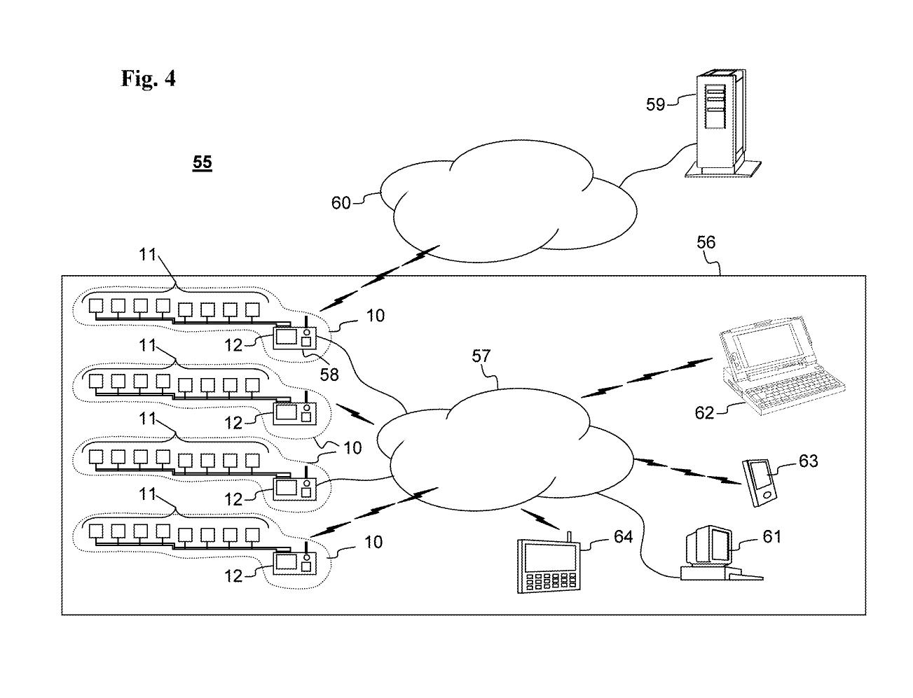

Reference is now made to FIG. 4, which is a simplified illustration of a network 55 of multi-metering devices 10, according to a preferred embodiment of the present invention.

As seen in FIG. 4, four multi-metering devices 10 are preferably mounted within a facility 56, such as an apartment building, or an office building, or an industrial facility. Preferably, each multi-metering device 10 contains one multi-metering controller 12 and eight electric-power measuring-devices 11. For example, the building 56 has eight floors with four apartments in each floor and one, three-phase electric-power measuring-devices 11 for each apartment. Thus, each multi-metering controller 12 measures electric power consumption for two floors.

The four multi-metering controllers 12 preferably communicate with each other via a local network 57. Preferably, one of the multi-metering controllers 12, identified by numeral 58, communicates with a remote server 59 via a long-range network 60.

It is appreciated that the local network 57 may be implement using a local area network (LAN), or a personal area network (PAN), whether cable-based or wireless, such as Ethernet, Universal Serial Bus (USB), WiFi (IEEE 802.11x), Bluetooth (IEEE802.15.1), Zigbee (IEEE802.15.4), RS-485, etc.

It is appreciated that the local network 60 may be implement using a wide area network or a metropolitan area network, whether cable-based or wireless, such as an Internet protocol (IP) network, The Internet, a trunked radio network (e.g. TETRA), a PLMN network (e.g. a cellular network), WiMAX (IEEE802.16), etc.

Preferably, local computers, such as tenants computers, such as desktop computer 61, or laptop computer 62, can access the multi-metering controllers 12 and, preferably by entering an identification code and a password, can retrieve power consumption information from the storage of the multi-metering controller 12.

Similarly, portable devices, such as PDA 63, typically used by a utility operator employee, can also access the multi-metering controllers 12, preferably by entering an identification code and a password, to retrieve power consumption information from the storage of the multi-metering controllers 12.

A local user terminal 64, preferably located in a tenant facility, such as an apartment, to enable the tenant to access the multi-metering controllers 12, The local user terminal 64, preferably using wireless communication technology, enables the tenant to retrieve power consumption information from the storage of the multi-metering controllers 12.

Preferably, the server 59 is operated by the utility operator to collect consumption information from the multi-metering device 10 and to remotely configure the multi-metering device 10 to compute the power consumption information according to specific power saving plans.

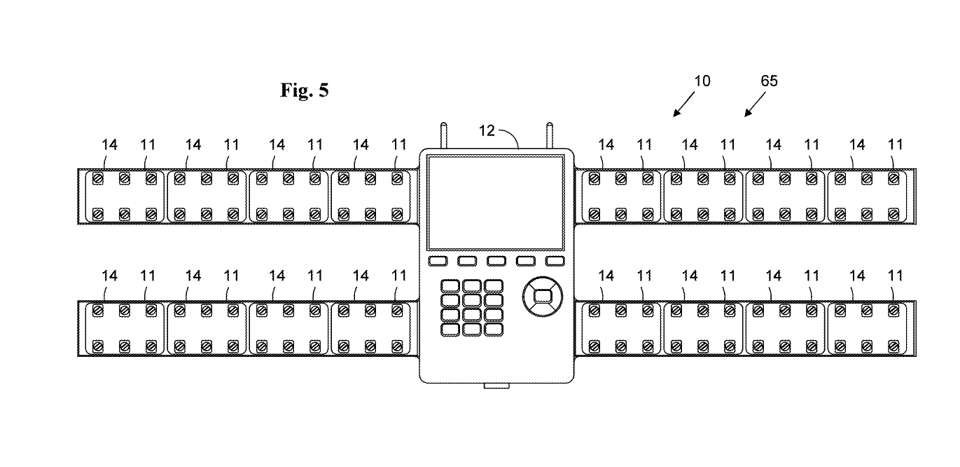

Reference is now made to FIG. 5, which is a simplified illustration of an integrated multi-metering device 65 according to a preferred embodiment of the present invention.

The integrated multi-metering device 65 is a multi-metering device 10 in which the electric-power measuring-devices 11 (preferably three-phase electric-power measuring-device 14) and the multi-metering controller 12 are housed in a single package and thus the wiring 29 are internal to the package (and not seen in FIG. 5).

It is appreciated that the multi-metering device 10, a well as the integrated multi-metering device 65, are therefore capable of measuring distributed consumption, preferably by performing the following sequence of operations:
Measuring instantaneous consumption, substantially concurrently, at a plurality of measuring points, thus providing instantaneous consumption measurement for each measuring point. The measurements of instantaneous consumption are preferably performed repeatedly or continuously. The measurements of instantaneous consumption are preferably performed by the measuring-devices 11.
Communicating the instantaneous consumption measurements to a local metering controller, preferably the multi-metering controller 12.
Computing, at the local metering controller (the multi-metering controller 12), periodical consumption measurement, for each of the measuring points, preferably independently.
Storing the periodical consumption measurement at the local metering controller (the multi-metering controller 12) for later retrieval.
Providing the periodical consumption measurements, preferably independently of each other.
Optionally, and preferably, communicating the periodical consumption measurements to:
   a user, via a user interface, such as user interface 33; and/or to
   a local computerized device, such as computer 61; and/or to
   a remote server, such as server 59.

It is appreciated that the operations involving:
measuring instantaneous consumption;
communicating the instantaneous consumption measurements; and
computing periodical consumption measurements;

are performed in a continuous and/or repeating manner.

It is appreciated that the measurements of instantaneous consumption can measure electric energy; and/or electric power; and/or electric current, and that the periodical consumption measurements can be performed for predefined periods. Preferably, the predefined periods are independently set for each measuring point.

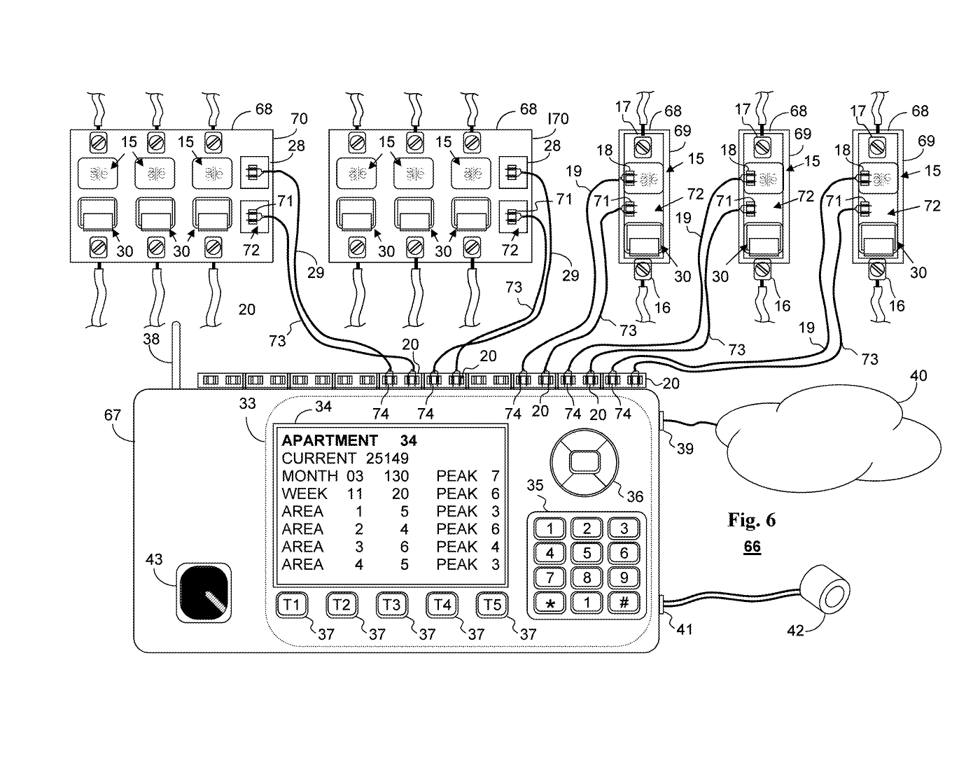

Reference is now made to FIG. 6, which is a simplified illustration of a remotely controlled multi-metering device 66, according to a preferred embodiment of the present invention.

The remotely controlled multi-metering device 66 is a preferably variation of the multi-metering device 10, preferably containing a remotely-controllable multi-metering controller 67 and preferably a plurality of controllable electric-power measuring-devices 68. The controllable electric-power measuring-devices 68 are typically single-phase electric-power measuring-devices 69 and/or three-phase electric-power measuring-devices 70, similarly to the electric-power measuring-devices 11. The controllable electric-power measuring-devices 68 preferably differ from the electric-power measuring-devices 11 by having an input connector 71, typically connected to an electromechanical actuator 72, which trips the fuse 30, upon receiving an electric signal via the input connector 71. The input connectors 71 are preferably connected via cables 73 to output ports 74 of the remotely-controllable multi-metering controller 67.

Thus, the remotely controlled multi-metering device 66 preferably enables the remote server 59 to control the remotely-controllable multi-metering controller 67, and preferably also to control the controllable electric-power measuring-devices 68.

For example, the remotely controlled multi-metering device 66 enables the remote server 59 to change computational parameters of remotely-controllable multi-metering controller 67, such as the periods for which remotely-controllable multi-metering controller 67 cumulates the power consumption. For example, the remote server 59 can instruct the remotely-controllable multi-metering controller 67 to separately cumulate power consumption for different hours of the day, for different days of the week, etc. according to peak and off-peak consumption periods.

Preferably, the remote server 59 can instruct remotely-controllable multi-metering controller 67 to connect or disconnect the power supply via a specific controllable electric-power measuring-devices 68, preferably by tripping the respective fuse 30.

It is appreciated that it is possible to configure a multi-metering device using controllable electric-power measuring-devices 68 and a multi-metering controller, which is not remotely-controllable. Such multi-metering device is capable of connecting and disconnecting power supply via each controllable electric-power measuring-device 68 based on internal considerations, and not under control from a remote server. Such internal considerations are preferably determined by the processor 49.

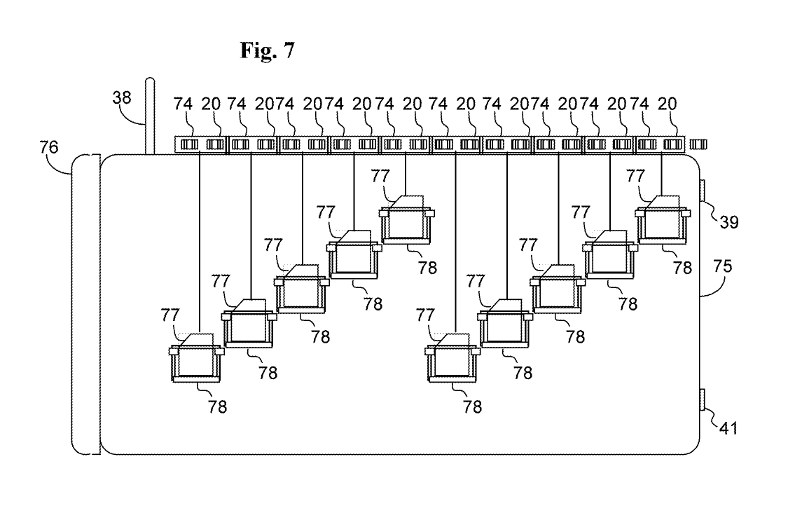

Reference is now made to FIG. 7, which is a simplified illustration of a subscriber-identifiable multi-metering controller 75 of a subscriber-identifiable multi-metering device, according to a preferred embodiment of the present invention.

The subscriber-identifiable multi-metering controller 75 is preferably a variation of the multi-metering controller 12, or a variation of the remotely-controllable multi-metering controller 67. FIG. 7 shows the subscriber-identifiable multi-metering controller 75 with the front panel 76 open.

Preferably, the subscriber-identifiable multi-metering controller 75 uses a subscriber identity module card 77 (SIM-card) to identify each subscriber. Preferably, each subscriber receives electric power via an electric-power measuring-device 68. Each SIM-card 77 identifying a subscriber is inserted into a SIM drive 78, which is associated with the input port 20 and the output ports 74 connected to the electric-power measuring-device 68 serving the specific subscriber.

Preferably, the SIM-card 77 can also serve as a payment confirmation (pre-paid SIM-card). Typically, the subscriber buys a pre-paid SIM-card, which contains a specific amount of allowable electricity consumption. The subscriber-identifiable multi-metering controller 75 measures the electricity consumed by the subscriber, or the monetary worth of the electricity consumed by the subscriber, and disconnects the subscriber upon consuming the allowable quantity. Preferably, the subscriber-identifiable multi-metering controller 75 disconnects the power supply to the subscriber by tripping the fuse 30 of the respective electric-power measuring-device 68. Typically, the subscriber can renew the power supply by buying and inserting a new SIM-card.

It is appreciated that the SIM-card can contain diverse power supply plans. For example, the SIM-card can contain a specific quantity of power supply (namely a quantity of Kilo-Watt-Hour) for off-peak periods and a separate quantity of power supply for peak periods.

Preferably, the subscriber can also re-load the SIM-card, preferably by contacting a payment center. To re-load the SIM-card the payment center preferably instructs the remote server 59 to re-load the SIM-card by communicating with the subscriber-identifiable multi-metering controller 75.

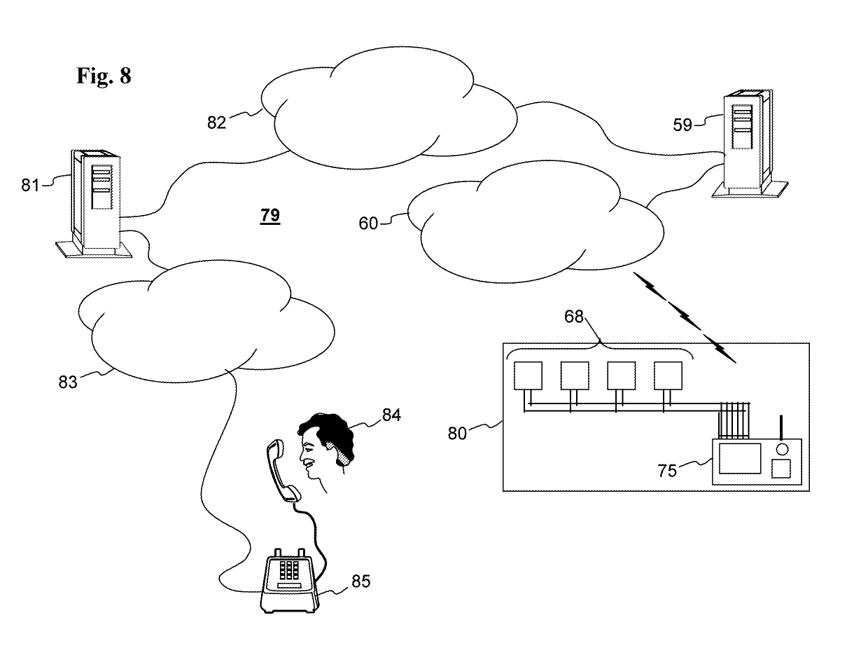

Reference is now made to FIG. 8, which is a simplified illustration of a utility billing system 79 for reloading remotely-controllable multi-metering devices according to a preferred embodiment of the present invention.

As shown in FIG. 8, the utility billing system 79 preferably contains one or more remotely-controllable multi-metering device 80, which preferably contains a remotely-controllable subscriber-identifiable multi-metering controller 75 controlling a plurality of electric-power measuring-device 68. The remotely-controllable multi-metering device 80 preferably communicates with a remote server 59 via the network 60. The remote server 59 preferably communicates with a payment support system 81 via a network 82, preferably a data communication network, such as the Internet. The payment support system 81 is typically a voice response system connecting to a telephone network 83. Typically, a subscriber 84, wishing to re-load a SIM-card in the remotely-controllable subscriber-identifiable multi-metering controller 75 uses a telephone terminal 85 (wireline or cellular) to call the payment support system 81 to process the payment to re-load the SIM-card. After the payment is processed the payment support system 81 communicates via the network 82 with the remote server 59, and instructs the remote server 59 to re-load the SIM card in the remotely-controllable subscriber-identifiable multi-metering controller 75. The remote server 59 then communicates via network 60 with the remotely-controllable subscriber-identifiable multi-metering controller 75. The remote server 59 provides the processor of the remotely-controllable subscriber-identifiable multi-metering controller 75 with the adequate code to load the appropriate SIM-card with the payment, or the consumption quantity worth of the payment.

It is expected that during the life of this patent many relevant sensors for measuring consumption of electric power as well as gas, water, etc. will be developed, and the scope of the terms herein, particularly of the terms “power”, “current” and “consumption”, is intended to include all such new technologies a priori.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims. All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention.

1. An electric metering system comprising:
a metering controller; and
a plurality of metering devices, each said metering device operative to provide instantaneous measurement of electric current within an associated electric conductor, each said metering device operative to communicate with said metering controller,
wherein said metering devices provide said instantaneous measurement to said metering controller, and
wherein said metering controller is operative to collect, store and retrieve said instantaneous measurements for each metering device independently.

2. An electric metering system according to claim 1 wherein said metering controller is additionally operative to provide measurement of energy consumed via each of said electric conductors within a predefined period.

3. An electric metering system according to claim 2 wherein said metering controller is additionally operative to store and retrieve said measurements of energy.

4. An electric metering system according to claim 1 wherein said metering controller and said plurality of metering devices are connected over a network, said network being at least one of a cable network, a fiberoptic network, a satellite network, an ad-hok network, a mesh network, a wireless network, a GSM network and a 4G network.

5. An electric metering system according to claim 4 wherein said wireless network being at least one of WiFi, Bluetooth, Zigbee, and an access point.

6. An electric metering system according to claim 4 wherein said cable network using a power-line carrier communication technology.

7. An electric metering system according to claim 1 wherein said metering controller is additionally operative to communicate with at least one of a computer, a PDA and a central server.

8. An electric metering system according to claim 7 wherein said metering controller is operative to communicate with said central server over a network, and wherein said network is at least one of a cable network and a wireless network.

9. An electric metering system according to claim 7 wherein said wireless network is at least one of a public land mobile network (PLMN) and wireless metropolitan network (MAN).

10. An electric metering system according to claim 1 wherein at least one metering device of said plurality of metering devices additionally comprises a current relay and is operative to receive a command to operate said relay, and wherein said metering controller is additionally operative to communicate said command to said metering device.

11. An electric metering system according to claim 10 additionally comprising at least one of a computer, a PDA, and wherein said metering controller is additionally operative to receive a command to operate said relay from at least one of a computer, a PDA and a central server and to forward said command to said metering device.

12. An electric metering system according to claim 1 wherein said metering controller is operative to receive a subscriber identity module and wherein said subscriber identity module is operative to identify a subscriber of a power utility service.

13. An electric metering system according to claim 12 wherein said subscriber identity module is a SIM card.

14. An electric metering system according to claim 12 wherein said subscriber identity module is operative to identify said subscriber for billing purpose.

15. An electric metering system according to claim 12 wherein said subscriber identity module is a pre-paid payment card.

16. An electric metering system according to claim 12 wherein said metering controller is connected to a remote billing system.

17. A method for measuring distributed consumption, the method comprising:
measuring instantaneous consumption, substantially concurrently, at a plurality of measuring points to provide instantaneous consumption measurement for each measuring point;
communication said instantaneous consumption measurements to a local controller;
computing, at said local metering controller, periodical consumption measurement, for each said measuring points;
storing said periodical consumption measurement at said local metering controller for later retrieval; and
providing said periodical consumption measurement independently of each other.

18. A method for measuring distributed consumption according to claim 17 wherein at least one of said steps of:
measuring instantaneous consumption,
communication said instantaneous consumption measurements, and
computing periodical consumption measurements,
comprises performing said at least one step in a manner that is at least one of continuous and repeating.

19. A method for measuring distributed consumption according to claim 17 additionally comprising the step of:
communicating periodical consumption measurements to at least one of:
a user,
a local computerized device, and
a remote server.

20. A method for measuring distributed consumption according to claim 17 wherein said consumption measurements comprise consumption of at least one of:
electric energy,
electric power, and
electric current.

21. A method for measuring distributed consumption according to claim 17 wherein said periodical consumption measurements are performed for predefined periods.

22. A method for measuring distributed consumption according to claim 17 wherein said predefined period is independently set for each measuring point.

23. A method for measuring distributed consumption according to claim 17 wherein said metering controller is additionally operative to perform the steps of:
receiving a subscriber identity module; and
identifying a subscriber of a power utility service.

24. A method for measuring distributed consumption according to claim 23 wherein said metering controller is additionally operative to perform the step of:
using said subscriber identity module as a pre-paid payment card.

25. A method for measuring distributed consumption according to claim 23 wherein said metering controller is additionally operative to perform the step of:
communicating at least one of payment, and consumption quantity worth of payment, with a remote billing system.
